(19) United States
(12) Patent Application Publication
(10) Pub. No.: US 2017/0040515 A1
(43) Pub. Date: Feb. 9, 2017

(54) SEMICONDUCTOR LIGHT EMITTING DEVICE AND METHOD OF MANUFACTURING THE SAME

(71) Applicant: SAMSUNG ELECTRONICS CO., LTD., Suwon-si (KR)

(72) Inventors: Jin Bock LEE, Hwaseong-si (KR); Su Yeol LEE, Seongnam-si (KR); Dong Hyuk JOO, Seoul (KR)

(73) Assignee: SAMSUNG ELECTRONICS CO., LTD., Suwon-si (KR)

(21) Appl. No.: 15/184,737

(22) Filed: Jun. 16, 2016

(30) Foreign Application Priority Data
Aug. 6, 2015 (KR) 10-2015-0111296

(51) Int. Cl. H01L 33/62; H01L 33/38; H01L 33/50; H01L 27/15; H01L 33/00; H01L 33/56; H01L 33/20; H01L 33/32

(52) U.S. Cl. CPC H01L 33/62; H01L 33/20; H01L 33/382; H01L 33/32; H01L 27/153; H01L 33/0075; H01L 33/56; H01L 33/502; H01L 2933/0066; H01L 2933/0025

(57) ABSTRACT

A semiconductor light emitting device is provided. The device includes a semiconductor stack, insulating layers, a current spreading layer, and first and second finger electrodes. The semiconductor stack includes a first and second conductivity-type semiconductor layers, an active layer between the first and second conductivity-type semiconductor layers, and a trench penetrating through the second conductivity-type semiconductor layer and the active layer to expose a portion of the first conductivity-type semiconductor layer. A first insulating layer is disposed on an inner sidewall of the trench. The current spreading layer is disposed on the second conductivity-type semiconductor layer. The first finger electrode is disposed on the exposed portion of the first conductivity-type semiconductor layer. The second insulating layer is disposed on the exposed portion of the first conductivity-type semiconductor layer to cover the first finger electrode. The second finger electrode is disposed in the trench and connected to the current spreading layer.

### CROSS-REFERENCE TO RELATED APPLICATION

This application claims the priority from Korean Patent Application No. 10-2015-0111296, filed on Aug. 6, 2015, with the Korean Intellectual Property Office, the disclosure of which is herein incorporated by reference.

### BACKGROUND

Apparatuses, devices, methods, and articles of manufacture related to the present inventive concept relate to a semiconductor light emitting device and a method of manufacturing the same.

Semiconductor light emitting devices are devices generating light in a particularly long wavelength band through recombination of electrons and holes. Such semiconductor light emitting devices have positive attributes such as relatively long lifespans, low power consumption, excellent initial operating characteristics, and the like, as compared to light sources based on filaments. Hence, demand for semiconductor light emitting devices is continuously increasing. In particular, group III nitride semiconductors capable of emitting blue light within a short-wavelength region of the visible spectrum have become prominent.

Research into semiconductor light emitting devices of which light emission efficiency may be improved is being actively conducted. In particular, various electrode structures for improving light emission efficiency and light output from semiconductor light emitting devices are being developed.

### SUMMARY

An aspect may provide a semiconductor light emitting device having a novel electrode structure in which light emission efficiency may be prevented from being deteriorated and light output may be improved, and a method of manufacturing the same.

According to an aspect of an exemplary embodiment, there is provided a semiconductor light emitting device comprising a semiconductor stack including a first conductivity-type semiconductor layer, a second conductivity-type semiconductor layer, an active layer between the first and second conductivity-type semiconductor layers, and a trench penetrating through the second conductivity-type semiconductor layer and the active layer to expose a portion of the first conductivity-type semiconductor layer; a first insulating layer disposed on an inner sidewall of the trench; a current spreading layer disposed on the second conductivity-type semiconductor layer; a first finger electrode disposed on the portion of the first conductivity-type semiconductor layer; a second insulating layer disposed on the exposed portion of the first conductivity-type semiconductor layer to cover the first finger electrode; and a second finger electrode disposed in the trench and connected to the current spreading layer.

The second finger electrode may be disposed on the second insulating layer to overlap the first finger electrode.

The second finger electrode may have a width greater than a width of the first finger electrode.

The current spreading layer may extend into the trench along an upper surface of the first insulating layer.

A region in which the second finger electrode and the current spreading layer are connected to each other may be located in the trench.

The second finger electrode may be disposed on the second insulating layer and may have an extension portion extending in a width direction to connect to a portion of the current spreading layer disposed outside of the trench.

The extension portion extending in the width direction may be provided as a plurality of extension portions, and the plurality of extension portions may be arranged along a length direction of the second finger electrode and spaced apart from each other.

The current spreading layer may extend into the trench along an upper surface of the first insulating layer, and the second finger electrode may be disposed on a portion of the current spreading layer located in the trench.

The second finger electrode may comprise two branched electrodes respectively disposed on portions of the current spreading layer that are adjacent to the first finger electrode.

A portion of the second finger electrode may be located on a portion of the current spreading layer disposed on an upper surface of the second conductivity-type semiconductor layer.

The first insulating layer may extend to a portion of an upper surface of the second conductivity-type semiconductor layer being adjacent to the trench.

The current spreading layer may comprise a transparent electrode layer.

The current spreading layer may comprise at least one of indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In4Sn3O12, and Zn(1-x)MgxO (zinc magnesium oxide, 0≦x≦1).

The semiconductor light emitting device may further comprise a first electrode pad connected to the first finger electrode and a second electrode pad connected to the second finger electrode.

A portion of the second finger electrode may be disposed on the second conductivity-type semiconductor layer, and the semiconductor light emitting device may further comprise a current blocking layer disposed between a portion of the second finger electrode and the second conductivity-type semiconductor layer.

According to another aspect of an exemplary embodiment, there is provided a semiconductor light emitting device comprising a semiconductor stack including a first conductivity-type semiconductor layer, a second conductivity-type semiconductor layer, an active layer between the first and second conductivity-type semiconductor layers, and a trench penetrating through the second conductivity-type semiconductor layer and the active layer to expose a portion of the first conductivity-type semiconductor layer; a first insulating layer disposed on an inner sidewall of the trench; a current spreading layer disposed on the second conductivity-type semiconductor layer and extending along an upper surface of the first insulating layer; a first finger electrode disposed on the exposed portion of the first conductivity-type semiconductor layer; a second insulating layer disposed in the trench to cover a portion of the current spreading layer together with the first finger electrode; and a second finger electrode disposed on the second insulating layer and connected to the current spreading layer.

The second finger electrode may have a width greater than a width of the first finger electrode, and the second finger electrode may have a region overlapping the first finger electrode in a length direction.

The second finger electrode may be disposed on a portion of the current spreading layer located in the trench.

The first insulating layer may comprise an extension portion extending toward a portion of an upper surface of the second conductivity-type semiconductor layer that is adjacent to the trench.

According to another aspect of an exemplary embodiment, there is provided semiconductor light emitting device comprising a semiconductor stack including a first conductivity-type semiconductor layer, a second conductivity-type semiconductor layer, an active layer between the first and second conductivity-type semiconductor layers, and a trench penetrating through the second conductivity-type semiconductor layer and the active layer to expose a portion of the first conductivity-type semiconductor layer; a current spreading layer disposed on an upper surface of the second conductivity-type semiconductor layer; a first finger electrode disposed on the exposed portion of the first conductivity-type semiconductor layer in the trench; an insulating layer disposed in the trench to cover the first finger electrode; and a second finger electrode disposed on an upper surface of the insulating layer and connected to a portion of the current spreading layer being adjacent to the trench.

The insulating layer may comprise a first insulating layer disposed on an inner sidewall of the trench, and a second insulating layer covering the first finger electrode.

According to another aspect of an exemplary embodiment, there is provided a method of manufacturing a semiconductor light emitting device, the method comprising forming a semiconductor stack by sequentially growing a first conductivity-type semiconductor layer, an active layer, and a second conductivity-type semiconductor layer on a substrate; forming a trench penetrating through the second conductivity-type semiconductor layer and the active layer in the semiconductor stack such that a portion of the first conductivity-type semiconductor layer is exposed; forming a first insulating layer on an inner sidewall of the trench; forming a current spreading layer on an upper surface of the second conductivity-type semiconductor layer and on the first insulating layer; forming a first finger electrode on the exposed portion of the first conductivity-type semiconductor layer; forming a second insulating layer on the exposed portion of the first conductivity-type semiconductor layer to cover the first finger electrode; and forming a second finger electrode in the trench to be connected to the current spreading layer.

The method may further comprise performing a heat treatment on the current spreading layer before the forming of the first finger electrode.

The heat treatment may be performed at a temperature equal to or higher than about 500° C.

According to another aspect of an exemplary embodiment, there is provided a semiconductor light emitting device comprising a trench that penetrates through an upper conductivity-type semiconductor layer and an active layer, and exposes a portion of a lower conductivity-type semiconductor layer; a first insulating layer disposed on inner sidewalls of the trench; a current spreading layer disposed on the upper conductivity-type semiconductor layer; a first finger electrode disposed on the exposed portion of the lower conductivity-type semiconductor layer and spaced apart from the first insulating layer and the current spreading layer; a second insulating layer disposed to cover the first finger electrode; and a second finger electrode disposed in the trench on the second insulating layer.

The current spreading layer may be disposed on the first insulating layer.

The second finger electrode may cover the first finger electrode in a direction orthogonal to the lower conductivity-type semiconductor layer.

The second finger electrode may extend outside of the trench.

The second finger electrode may be disposed on the current spreading layer.

The second finger electrode may be disposed on the current spreading layer without covering the first finger electrode.

### BRIEF DESCRIPTION OF DRAWINGS

The above and other aspects will be more clearly understood from the following detailed description taken in conjunction with the accompanying drawings, in which:

FIG. 1 is a schematic plan view of a semiconductor light emitting device according to an exemplary embodiment;

FIG. 2 is a schematic cross-sectional view of the semiconductor light emitting device taken along line of FIG. 1;

FIG. 3 is a side cross-sectional view schematically illustrating a portion “A” of the semiconductor light emitting device of FIG. 2;

FIGS. 4A to 4F are cross-sectional views illustrating a process of manufacturing a semiconductor light emitting device according to an exemplary embodiment;

FIG. 5 is a plan view schematically illustrating a semiconductor light emitting device according to an exemplary embodiment;

FIG. 6A is a schematic cross-sectional view of the semiconductor light emitting device taken along line of FIG. 5;

FIG. 6B is a schematic cross-sectional view of the semiconductor light emitting device taken along line II-If of FIG. 5;

FIG. 7 is a schematic plan view of a semiconductor light emitting device according to an exemplary embodiment;

FIG. 8 is a schematic cross-sectional view of the semiconductor light emitting device taken along line X-X′ of FIG. 7;

FIG. 9 is a schematic cross-sectional view of a semiconductor light emitting device according to an exemplary embodiment;

FIGS. 10 and 11 are side cross-sectional views of a package in which a semiconductor light emitting device illustrated in FIG. 1 is employed;

FIG. 12 is a perspective view of a backlight device in which a semiconductor light emitting device according to an exemplary embodiment is employed;

FIG. 13 is a cross-sectional view of a direct-type backlight device in which a semiconductor light emitting device according to an exemplary embodiment is employed;

FIG. 14 is an exploded perspective view of a display device according to an exemplary embodiment; and

FIG. 15 is an exploded perspective view of a bulb-type light emitting diode (LED) lamp including a semiconductor light emitting device according to an exemplary embodiment.

### DETAILED DESCRIPTION

Hereinafter, exemplary embodiments will be described as follows with reference to the attached drawings.

The present inventive concept may, however, be exemplified in many different forms and should not be construed as being limited to the specific exemplary embodiments set forth herein. Rather, these exemplary embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that, though the terms “first”, “second”, “third”, etc. may be used herein to describe various members, components, regions, layers and/or sections, these members, components, regions, layers and/or sections should not be limited by these terms. These terms are only used to distinguish one member, component, region, layer or section from another region, layer or section. Thus, a “first” member, component, region, layer or section discussed below could be termed a “second” member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular exemplary embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, exemplary embodiments will be described with reference to schematic views illustrating various exemplary embodiments. In the drawings, for example, due to manufacturing techniques and/or tolerances, modifications of the shape shown may be estimated. Thus, exemplary embodiments should not be construed as being limited to the particular shapes of regions shown herein, for example, to include a change in shape results in manufacturing. The following exemplary embodiments may also be constituted by one or a combination thereof.

The contents of the present inventive concept described below may have a variety of configurations and propose only a configuration herein, but are not limited thereto.

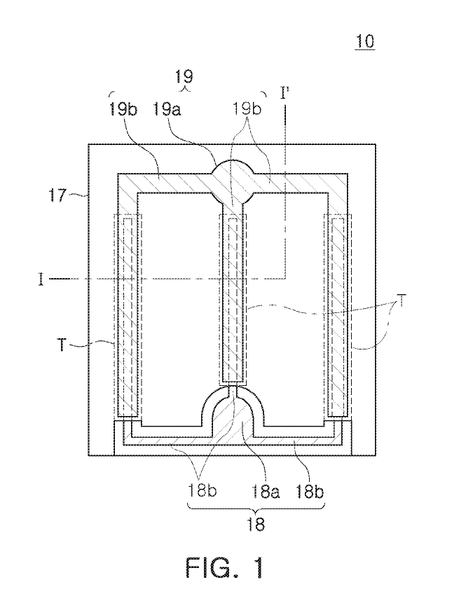

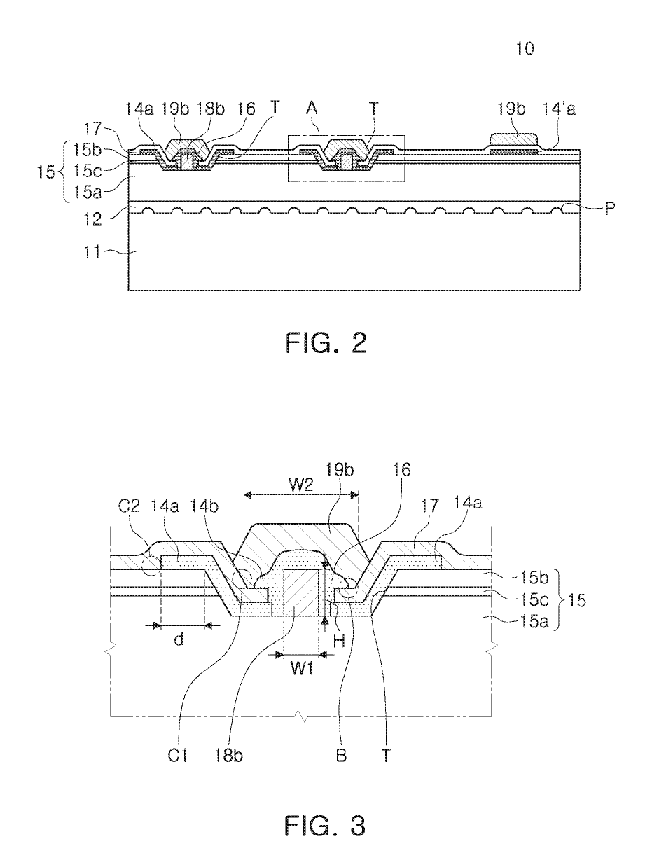

FIG. 1 is a schematic plan view of a semiconductor light emitting device according to an exemplary embodiment. FIG. 2 is a schematic cross-sectional view of the semiconductor light emitting device taken along line I-I′ of FIG. 1.

Referring to FIG. 1 and FIG. 2, a semiconductor light emitting device 10 may include a substrate 11 and a semiconductor stack 15 disposed on the substrate 11.

The semiconductor stack 15 may include a first conductivity-type semiconductor layer 15a, an active layer 15c, and a second conductivity-type semiconductor layer 15b. A buffer layer 12 may be disposed between the substrate 11 and the first conductivity-type semiconductor layer 15a.

The substrate 11 may be an insulating substrate, a conductive substrate, or a semiconductor substrate. For example, the substrate 11 may be a sapphire, SiC, Si, MgAl₂O₄, MgO, LiAlO₂, LiGaO₂, or GaN substrate. Concave-convex portions P may be fainted on an upper surface of the substrate 11. The concave-convex portions P may allow for an improved quality of a single crystal grown thereon while improving light extraction efficiency. The concave-convex portions P employed in the exemplary embodiment may have an uneven structure in which hemispherical shaped protrusions or other various shapes are formed.

The buffer layer 12 may be an InₓAl_{y}Ga_{1-x-y}N (0≦x≦1, 0≦y≦1) layer. For example, the buffer layer 12 may be an AlN, AlGaN, or InGaN layer. The buffer layer 12 may also be formed by combining a plurality of layers with each other or gradually changing a composition thereof.

The first conductivity-type semiconductor layer 15a may be a nitride semiconductor layer satisfying n-type AlₓIn_{y}Ga_{1-x-y}N (0≦x≦1, 0≦y≦1, 0≦x+y≦1), and an n-type impurity may be silicon (Si). For example, the first conductivity-type semiconductor layer 15a may be an n-type GaN layer. The second conductivity-type semiconductor layer 156 may be a nitride semiconductor layer satisfying p-type AlₓIn_{y}Ga_{1-x-y}, and a p-type impurity may be magnesium (Mg). For example, the second conductivity-type semiconductor layer 15b may be a p-type AlGaN/GaN layer. The active layer 15c may have a multiple quantum well structure (MQW) in which quantum well layers and quantum harrier layers are alternately stacked. For example, when a nitride semiconductor is used, the active layer 15c may have a GaN/InGaN MQW structure.

In some exemplary embodiments, a first electrode 18 and a second electrode 19 may be provided. The first electrode 18 may include a first electrode pad 18a, and a plurality of first finger electrodes 18a extending from the first electrode pad 18a. The second electrode 19 may include a first electrode pad 19a and a plurality of second finger electrodes 19b extending from the second electrode pad 19a. In the present specification, the term ‘finger electrode’ may refer to an electrode extended from an electrode pad connected to an external circuit. In some exemplary embodiments, the finger electrode is illustrated as having a lengthwise extended form, but the shape of the finger electrode is not particularly limited and may also have various shapes. For example, the finger electrode may have a bent form or a form in which one finger is branched into a plurality of fingers. The finger electrodes may have different widths depending on length directions thereof.

As shown on the left-hand side in FIG. 2, the first finger electrode 18b may be disposed on a portion of the first conductivity-type semiconductor layer 15a exposed by a trench T. The trench T may be formed to penetrate through the second conductivity-type semiconductor layer 15b and the active layer 15c. The first finger electrode 18b may be disposed on a bottom surface of the trench T, and may be connected to the exposed portion of the first conductivity-type layer 15a. The remainder of the plurality of first finger electrodes 18b have a similar configuration and thus a repeated description will be omitted for conciseness.

The trench T employed in this exemplary embodiment may have three branches to correspond to three first finger electrodes 18b as shown in FIG. 1. However, the number and shapes of the trenches T are not limited thereto, and may be variously formed according to the number and shape of the first finger electrodes 18b.

The second finger electrodes 19b may be disposed together with the first finger electrodes 18b in the trenches T as shown in FIG. 1. The detailed arrangement of the first finger electrodes 18b and the second finger electrodes 19b will be described in detail with reference to FIG. 3. FIG. 3 is an enlarged view illustrating a portion “A” showing an area around a trench T of the semiconductor light emitting device 10 of FIG. 2.

As illustrated in FIG. 3, a first insulating layer 14a may be disposed along an inner sidewall of the trench T. A current spreading layer 17 disposed on the second conductivity-type semiconductor layer 15b may extend into the trench T along an upper surface of the first insulating layer 14a. For example, the current spreading layer 17 may be formed of a transparent electrode material, for example, a conductivity oxide such as ITO.

A second insulating layer 14b may be disposed in the trench T to cover the first finger electrode lab. The second finger electrode 19b may be disposed on the second insulating layer 14b to overlap the first finger electrode lab. The second insulating layer 14b may be formed to cover the exposed region of the first conductivity-type semiconductor layer 15a in the trench T. As illustrated in FIG. 3, the second insulating layer 14b may cover a portion of the current spreading layer 17.

The second finger electrode 19b may be connected to a portion of the current spreading layer 17 located in the trench T. The second finger electrode 19b may be formed to be respectively connected to portions of the current spreading layer 17 disposed on two sides of the second insulating layer 14b. A width W2 of the second finger electrode 19b may be greater than a width W1 of the first finger electrode 18b. The first finger electrode 18b may have a relatively large thickness H. For example, the thickness H of the first finger electrode 18b may be about 50% or more of a depth of the trench T and, in some exemplary embodiments, may be greater than a depth of the trench T. The thickness H of the first finger electrode 18b may be substantially the same as a thickness of the first electrode pad 18a.

In some exemplary embodiments, the second finger electrode 19b may have a portion that is not disposed in the trench T. For example, as illustrated in FIG. 1, a portion of the second finger electrode 19b adjacent to the second electrode pad 19a may not be disposed in the trench T, but may be disposed on the second conductivity-type semiconductor layer 15b. With reference to the right-hand side of FIG. 2, a portion of the second finger electrode 19b may be disposed above the second conductivity-type semiconductor layer 15b to be located on the current spreading layer 17. In this case, a current blocking layer 14′a for uniform current spreading may be disposed below the current spreading layer 17 to correspond to a position of the portion of the second finger electrode 19b that is disposed above the second conductivity-type semiconductor layer 15b and located on the current spreading layer 17. The current blocking layer 14′a may be formed simultaneously with formation of the first insulating layer 14a, and may be formed of an insulating material the same as a material of the first insulating layer 14a.

In a specific example, the first insulating layer 14a may be a DBR multilayer film in which dielectric layers having different refractive indices are alternately stacked. As the first insulating layer 14a has a DBR multilayer structure, light extraction efficiency may be further improved. The current blocking layer 14′a may also be configured of a DBR multilayer film in a manner similar to the first insulating layer 14a. However, light extraction efficiency may be improved by additionally forming a reflective metal layer on a surface of a passivation layer such as the first insulating layer 14a.

In some exemplary embodiments, since the current spreading layer 17 extends into the trench T, a region C1 (see FIG. 3) in which the second finger electrode 19b and the current spreading layer 17 are connected to each other may be located in the trench T. As such, since the second finger electrode 19b is located on a nonluminous region from which the active layer 15c has been removed, light loss due to the second finger electrode 19b may be significantly reduced.

As illustrated in FIG. 3, the first insulating layer 14a may extend to a portion of an upper surface of the second conductivity-type semiconductor layer 15b in an area adjacent to the trench T. In addition, the current spreading layer 17 may extend along an extended portion of the first insulating layer 14a to be connected to the second conductivity-type semiconductor layer 15b. In some exemplary embodiments, a contact start point C2 at which a connection between the current spreading layer 17 and the second conductivity-type semiconductor layer 15b starts may be determined by a length d of the extended portion of the first insulating layer 14a, as shown in FIG. 3. In detail, for example, when the length d of the extended portion of the first insulating layer 14a is increased, the contact start point C2 may be farther away from the second finger electrode 19b, and thus, a current path may be changed. For example, when the length d of the extended portion is increased, the distribution of current may be more uniform in the semiconductor stack 15. As a result, a driving voltage of the semiconductor light emitting device 10 may be reduced.

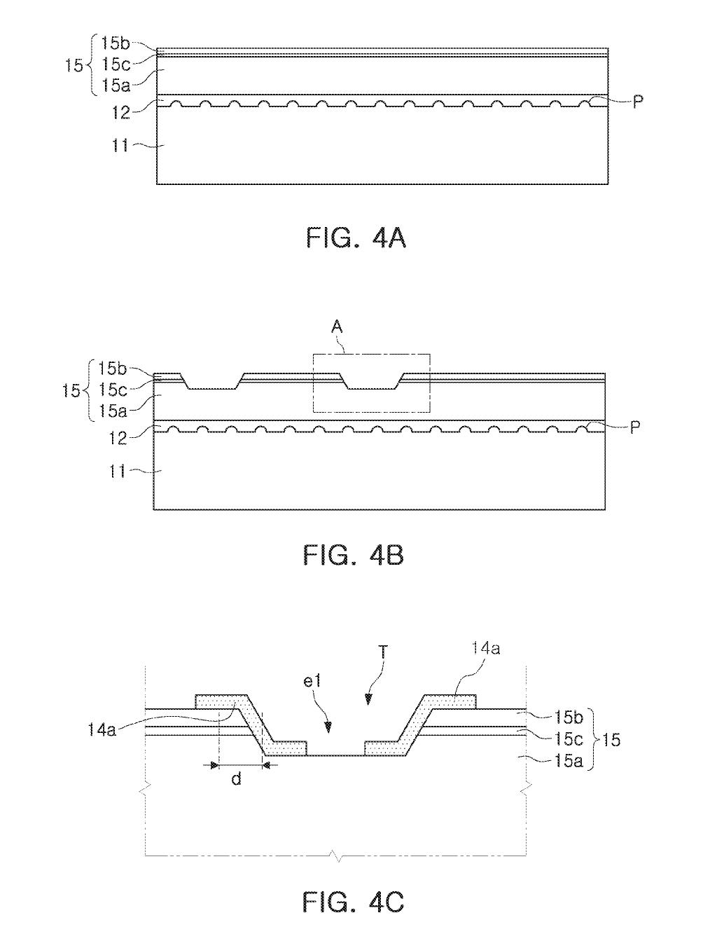

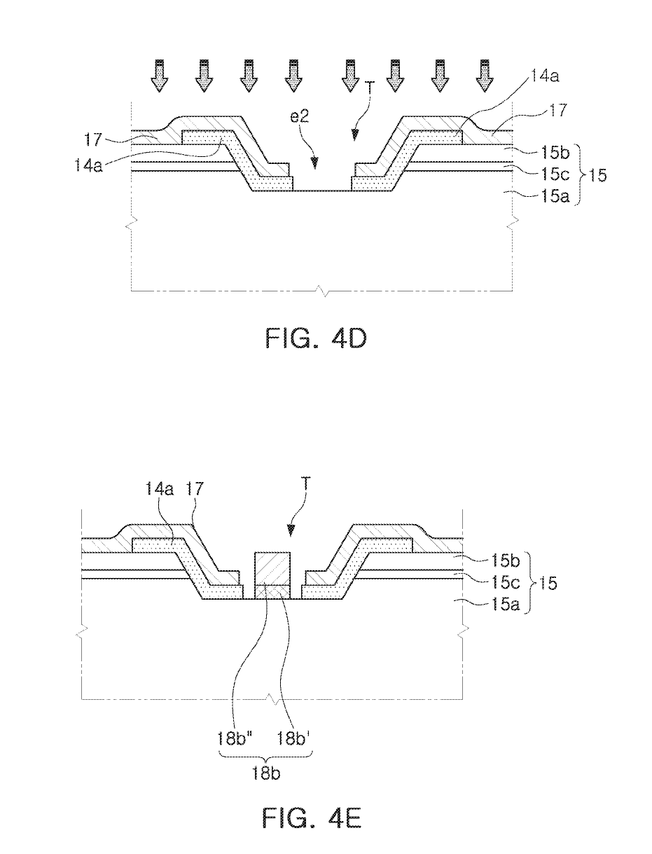

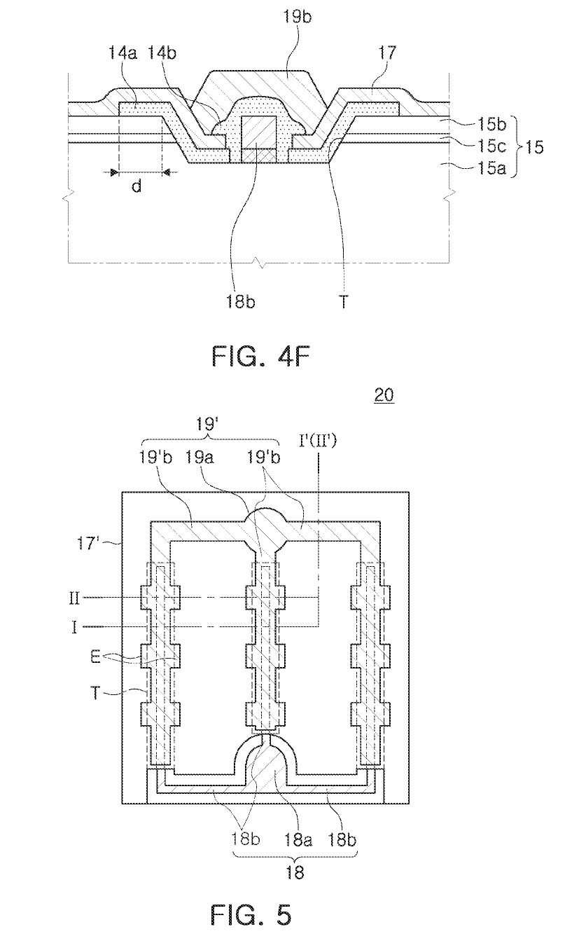

FIGS. 4A to 4F are cross-sectional views illustrating a process of manufacturing a semiconductor light emitting device according to an exemplary embodiment.

As illustrated in FIG. 4A, a buffer layer 12 may be formed on a substrate 11, and a semiconductor stack 15 for a light emitting device may be formed on the buffer layer 12.

The semiconductor stack 15 may include a first conductivity-type semiconductor layer 15a, an active layer 15c, and a second conductivity-type semiconductor layer 15b, and may be a nitride semiconductor as described above. The semiconductor stack 15 may be grown on the substrate 11 using a process such as metal organic chemical vapor deposition (MOCVD), molecular beam epitaxy (MBE), or hydride vapor phase epitaxy (HVPE).

Subsequently, as illustrated in FIG. 4B, a trench T to which a portion of the first conductivity-type semiconductor layer 15a is exposed may be formed by partially removing the second conductivity-type semiconductor layer 15b and the active layer 15c. In some exemplary embodiments, a portion of the first conductivity-type semiconductor layer 15a may also be removed.

The portion of the first conductivity-type semiconductor layer 15a exposed by the trench T may be provided as a region in which a first finger electrode is to be formed. Such a removal process may be performed by a selective etching process using a mask. The trench T shown in FIG. 4B may also be formed to obtain a region in which the first electrode pad 18a (FIG. 1) is to be formed.

FIGS. 4C to 4F are enlarged views of a trench region “A” of FIG. 4B, illustrating arrangement processes of first finger electrodes 18b and second finger electrodes 19b.

As illustrated in FIG. 4C, a first insulating layer 14a may be formed on an inner sidewall of the trench T.

The first insulating layer 14a formed in the present process may be formed in such a manner that a portion e1 of a bottom surface of the trench T is exposed. The exposed portion e1 may be provided as a region in which the first finger electrode 18b is formed. The first insulating layer 14a may be a SiO₂ or a SiN layer. A current spreading layer 17 to be formed in a subsequent process may extend into the trench T using the first insulating layer 14a. Such an extension may facilitate a connection of the second finger electrode 19b and the current spreading layer 17 to each other.

The first insulating layer 14a employed in the exemplary embodiment shown in FIG. 4C may extend to a portion of an upper surface of the second conductivity-type semiconductor layer 15b, on the second conductivity-type semiconductor layer 15b. As described above, a current path may be changed by adjusting a length d of the extended portion of the first insulating layer 14a, thereby exhibiting an effect of reducing a level of an operating voltage.

Subsequently, as illustrated in FIG. 4D, the current spreading layer 17 may be formed on the second conductivity-type semiconductor layer 15b and the first insulating layer 14a.

As described above, the current spreading layer 17 formed in the present process may extend into the trench T along the first insulating layer 14a. An extension portion of the current spreading layer 17 extending into the trench T may have an opening e2 through which a bottom surface of the trench T is exposed. The current spreading layer 17 may be connected to an upper surface of the second conductivity-type semiconductor layer 15b.

For effective current spreading, the current spreading layer 17 may be formed on a substantially entire upper surface of the second conductivity-type semiconductor layer 15b. (For example, see FIG. 2). A connection area between the second conductivity-type semiconductor layer 15b and the current spreading layer 17 may be determined by the length d of the extension portion of the first insulating layer 14a, as well as a distance from the trench T to a contact start point being defined thereby.

For example, the current spreading layer 17 may be formed of a conductive oxide as a transparent electrode material. For example, the current spreading layer 17 may contain at least one of indium tin oxide (ITO), zinc-doped indium tin oxide (ZITO), zinc indium oxide (ZIO), gallium indium oxide (GI), zinc tin oxide (ZTO), fluorine-doped tin oxide (FTO), aluminum-doped zinc oxide (AZO), gallium-doped zinc oxide (GZO), In₄Sn₃O₁₂, and Zn₍₁₋ₓ₎MgₓO (zinc magnesium oxide, 0≦x≦1.).

In order to obtain electrical/optical characteristics, the conductive oxide may be additionally subjected to a heat treatment process after a deposition process. A heat treatment temperature of the heat treatment process may be, for example, about 500° C. or higher. In some exemplary embodiments, before forming the first finger electrode, a heat treatment process for the current spreading layer 17 may be performed, and damage to the first finger electrode 18b may be fundamentally prevented.

Subsequently, as illustrated in FIG. 4E, the first finger electrode 18b may be formed on an exposed region of the first conductivity-type semiconductor layer 15a.

The first finger electrode 18b may respectively include a material such as Ag, Ni, Al, Rh, Pd, Ir, Ru, Mg, Zn, Pt, Au, or the like, and may have a structure of a single layer, or a structure of two or more layers. For example, the first finger electrode 18b may include a first layer 18b for ohmic contact and a second layer 18b″ disposed on the first layer 18b′. The first layer 18b′ may be formed of Ni, Cr, or a combination thereof. The second layer 18b″ may be formed of Au, Al, or a combination thereof. In a specific example, a barrier layer such as a Mo, Pt, W, TiV, or TiW layer may be formed between the first and second layers 18b′ and 18b″.

Subsequently, as illustrated in FIG. 4F, a second insulating layer 14b may be formed in the exposed region of the first conductivity-type semiconductor layer 15a to cover the first finger electrode 18b, and then, the second finger electrode 19b may be formed on the second insulating layer 14b.

In the example embodiment shown in FIG. 4F, the second insulating layer 14b may be formed in the trench T to cover the first finger electrode 18b. In some exemplary embodiments, the second insulating layer 14b may fill a space of the trench T. In the trench T, portions of the first insulating layer 14a and the current spreading layer 17 may be covered by the second insulating layer 14b. The second insulating layer 14b may be formed of a material similar to that of the first insulating layer 14a.

The second finger electrode 19b may be formed on the second insulating layer 14b while having a width wide enough to be connected to the current spreading layer 17 adjacent to the second insulating layer 14b. As such, since the second finger electrode 19b may be disposed on a nonluminous region from which the active layer 15c has been removed, light loss due to the second finger electrode 19b may be significantly reduced. The second finger electrode 19b may be formed of a material appropriate for the formation of ohmic contact with the current spreading layer 17. The second finger electrode 19b may be formed of a metal similar to that of the first finger electrode 18b, and for example, may include Ag or Ag—Ni.

In the previous process described above, although the electrode formation process is described as a process in which the first and second finger electrodes are formed, first and second electrode pads 18a and 19a may also be respectively formed of the same material simultaneously with the process in which the first and second finger electrodes are formed. In such a case, after the second finger electrode 19b is formed, a bonding metal for the first and second electrode pads 18a and 19a may be additionally deposited in a single process. The first and second electrode pads 18a and 19a may include Au, Sn, or Au/Sn.

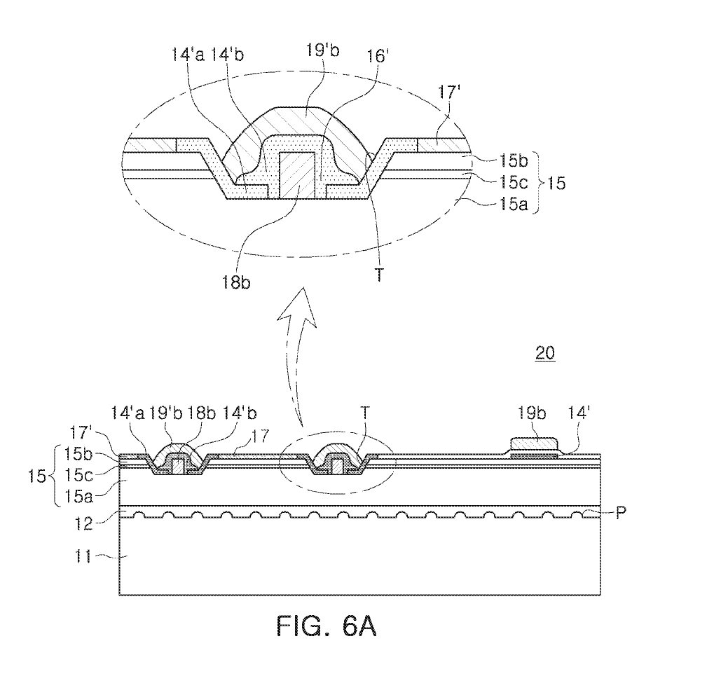

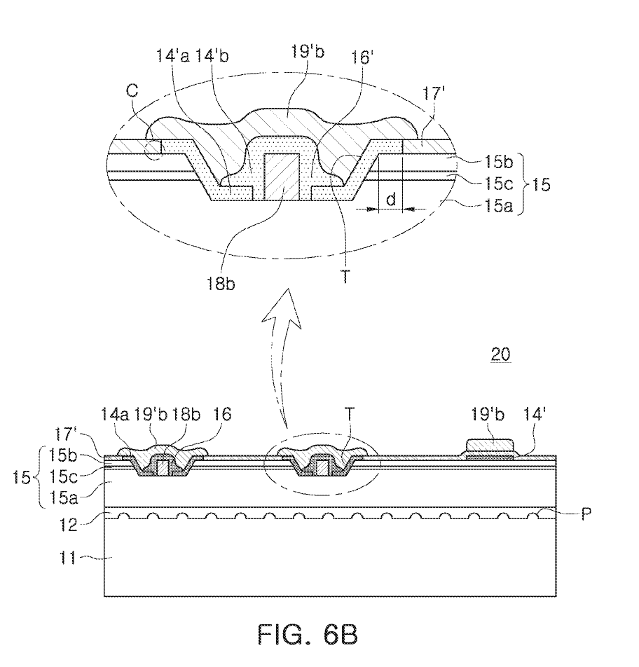

FIG. 5 is a plan view schematically illustrating a semiconductor light emitting device according to an exemplary embodiment. FIGS. 6A and 6B are schematic cross-sectional views of a semiconductor light emitting device taken along line I-I′ and line II-II′ of FIG. 5, respectively.

A semiconductor light emitting device 20 illustrated in FIG. 5 may be understood as having a structure the same as or similar to the structure of the semiconductor light emitting device 10 illustrated in FIGS. 1 and 2, except for constituent elements arranged in the vicinity of a trench T.

A first finger electrode 18b may be disposed on a bottom surface of the trench T, for example, on an exposed region of the first conductivity-type semiconductor layer 15a in a manner similar to the exemplary embodiment described above, while a current spreading layer 17′ may not extend to an interior of the trench T, and may be disposed limited to an upper surface of a second conductivity-type semiconductor layer 15b. Within the trench T, a first insulating layer 14′a may be formed along an inner sidewall of the trench T without an extended portion of the current spreading layer 17′ in the trench, and the second insulating layer 14b may cover the first finger electrode 18b in the trench T.

A second finger electrode 19′b employed in this exemplary embodiment may be disposed on the second insulating layer 1413, and may have extension portions E extending in a width direction of the second finger electrode 19′b. As illustrated in FIG. 5, the extension portions E extending in the width direction may be provided in plural, and may be spaced apart from each other in a length direction of the second finger electrode 19′b.

As illustrated in FIG. 6A which illustrates I-I′ in FIG. 5, a portion of the second finger electrode 19′h that does not include the extension portions E may be disposed on the first insulating layer 14′a in the trench T. In a manner different therefrom, in a portion of the second finger electrode 19′b that does include the extension portions E, the extension portion E extending from the second finger electrode 19′b may be connected to a portion of the current spreading layer 17′ located externally of the trench T as illustrated in FIG. 6B which illustrates section II-II′ in FIG. 5.

As such, as shown in FIG. 6B, a main region of the second finger electrode 19′b may be located in the trench T, and may be electrically connected to the current spreading layer 17′ at “C” via a partially extended portion E of the second finger electrode 19′b.

In such a structure, since the current spreading layer 17′ is formed on an upper surface of the second conductivity-type semiconductor layer 15b, the current spreading layer 17′ may be formed before forming the first finger electrode 18b, and the first finger electrode 18b may be formed after a heat treatment process on the current spreading layer 17′ is performed.

In the exemplary embodiment illustrated in FIG. 6B, the first insulating layer 14′a may have an extension portion extended a length d to a portion of an upper surface of the second conductivity-type semiconductor layer 15b being adjacent to the trench T, and a contact start point “C” may be adjusted by the length d, thereby controlling a current spreading effect.

The exemplary embodiment illustrated in FIG. 6B illustrates a case in which the region “C” connected to the current spreading layer 17′ is located outside of the trench T, but is not limited thereto. In some exemplary embodiments, the current spreading layer 17′ may extend into the trench T together with the first insulating layer 14′a as in the current spreading layer 17 and the first insulating layer 14 illustrated in FIG. 3, and may be connected to an extended portion of the current spreading layer 17 as in FIG. 3. In addition, for example, when the current spreading layer 17′ is located externally of the trench T, the entirety of a width of the second finger electrode 19′b may extend in a length direction to be electrically connected to the current spreading layer 17′.

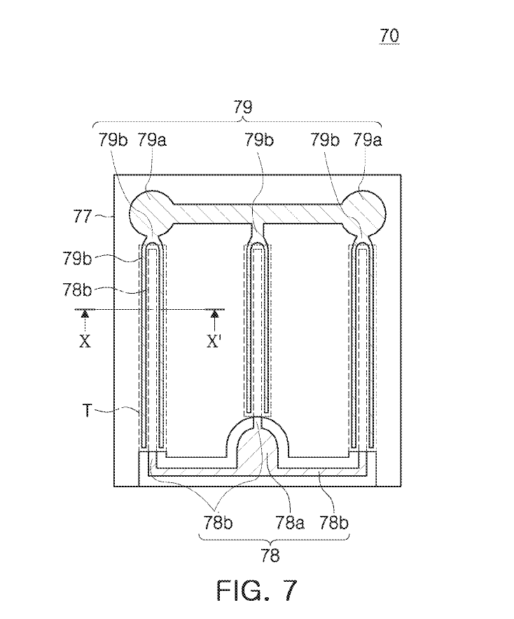

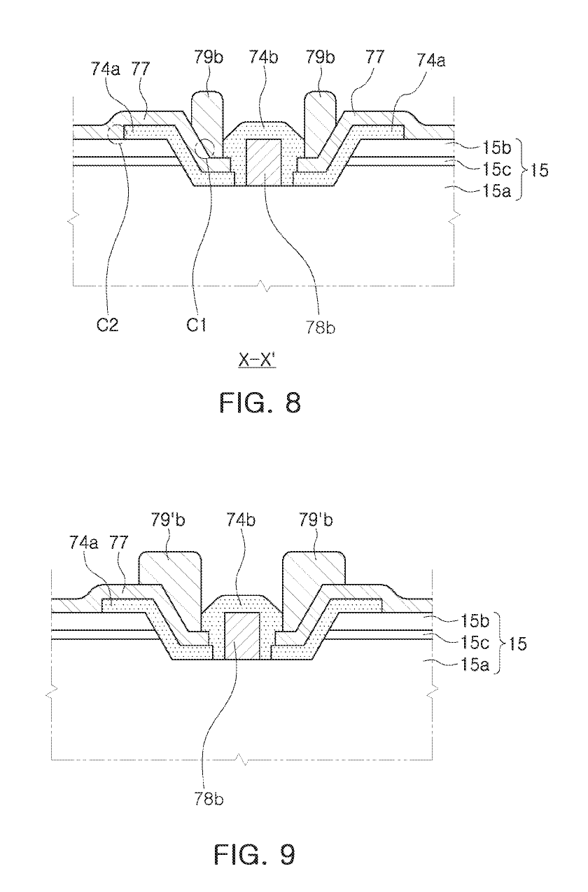

FIG. 7 is a schematic plan view of a semiconductor light emitting device according to an exemplary embodiment. FIG. 8 is a schematic cross-sectional view of the semiconductor light emitting device taken along line X-X′ of FIG. 7.

A semiconductor light emitting device 70 illustrated in FIG. 7 may be understood as having a structure, with the arrangement of electrodes, the same as or similar to the structure of the semiconductor light emitting device 10 illustrated in FIGS. 1 and 2, except for constituent elements arranged in the vicinity of a trench T.

The semiconductor light emitting device 70 illustrated in FIG. 7 may include one first electrode pad 78a with three first finger electrodes 78b extended therefrom, and two second electrode pads 79a with three second finger electrodes 79b extended therefrom, in a manner different from the previously described exemplary embodiments. The first and second electrodes 78 and 79 may be arranged in a vertically symmetrical form.

In this exemplary embodiment, the current spreading layer 77 may extend together with the first insulating layer 74a into the trench T in which the first finger electrode 78b is disposed. In detail, in a manner similar to the exemplary embodiment of FIG. 3, the current spreading layer 77 may be disposed on the second conductivity-type semiconductor layer 15b, and may extend into the trench T along the first insulating layer 74a.

In this exemplary embodiment, the second finger electrode 79b may be disposed on a portion of the current spreading layer 77 located in the trench T as shown in FIG. 8. As illustrated in FIGS. 7 and 8, the second finger electrode 79b may include two branched electrodes respectively disposed in regions of the current spreading layer 77 on two sides of the first finger electrode 78b. In such an arrangement, the second finger electrode 79b may have a connection region C1 connected to the current spreading layer 77, and the current spreading layer 77 may extend along the first insulating layer 74a to have a connection region C2 connected to the second conductivity-type semiconductor layer 15b.

The second insulating layer 74b may be disposed to cover the first finger electrode 78b to allow the first finger electrode 78b and the second finger electrode 79b to be insulated from each other. In some exemplary embodiments, the second insulating layer 74b may be disposed between the first and second finger electrodes 78b and 79b without completely covering the first finger electrode 78b. Alternatively, in other exemplary embodiments, the second insulating layer 74b may be omitted in a case in which the first and second finger electrodes 78b and 79b are sufficiently separated from each other by a gap therebetween.

The second finger electrode 79b employed in the exemplary embodiment is located in the trench T, and thus, extraction of light generated in the active layer 15c may not be influenced by the second finger electrode, and light output may be significantly improved.

Although the exemplary embodiment of FIGS. 7 and 8 illustrates a form in which a majority of regions of the second finger electrode 79b are located in the trench T, in other exemplary embodiments, the second finger electrode 79b may be disposed in such a manner that a portion of the second finger electrode 79b is disposed on a portion of the current spreading layer 77 located on an upper surface of the second conductivity-type semiconductor layer 15b, as illustrated in FIG. 9.

A semiconductor light emitting device according to the exemplary embodiments described above may be employed as a light source in various types of products.

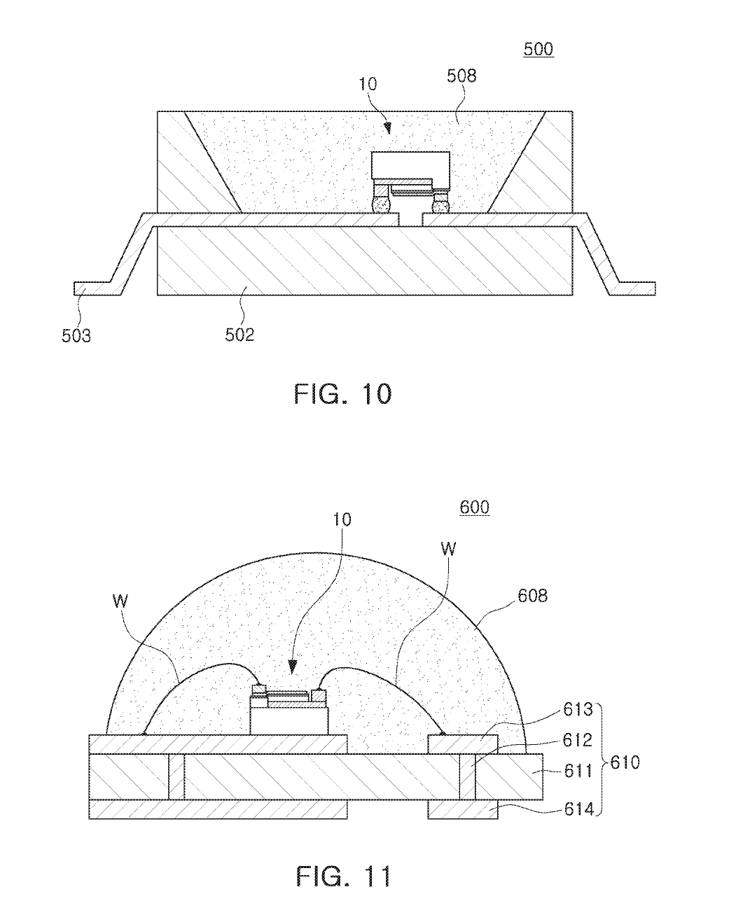

FIG. 10 is a cross-sectional view of a package 500 in which the semiconductor light emitting device 10 illustrated in FIG. 1 is employed.

The semiconductor light emitting device package 500 illustrated in FIG. 10 may include a semiconductor light emitting device 10 illustrated in FIG. 1, a package body 502, and a pair of lead frames 503.

The semiconductor light emitting device 10 may be mounted on a lead frame 503, and a respective electrode pad of the semiconductor light emitting device 10 may be electrically connected to the lead frame 503 in a flip-chip bonding scheme. In some exemplary embodiments, the semiconductor light emitting device 10 may be mounted in other regions other than on the lead frame, for example, mounted on a package body 502. In addition, the package body 502 may have a cup-shaped recess portion to improve light reflection efficiency. An encapsulation body 508 formed of a light transmitting material may be formed in the recess portion to encapsulate the semiconductor light emitting device 10.

FIG. 11 is a cross-sectional view of a package 600 in which a semiconductor light emitting device 10 illustrated in FIG. 1 is employed.

A semiconductor light emitting device package 600 illustrated in FIG. 11 may include a semiconductor light emitting device 10 illustrated in FIG. 1, a mounting substrate 610, and an encapsulation body 608. The semiconductor light emitting device 10 may be mounted on the mounting substrate 610 to be electrically connected thereto via a wire W. The mounting substrate 610 may include a substrate body 611, an upper electrode 613, a lower electrode 614, and a through electrode 612 connecting the upper electrode 613 to the lower electrode 614 to each other. The mounting substrate 610 may be provided as a substrate such as a printed circuit board (PCB), a metal-core printed circuit board (MCPCB), an MPCB, a flexible printed circuit board (FPCB), or the like, and the structure of the mounting substrate 610 may be variously applied.

The encapsulation body 608 may have a dome-shaped lens structure of which an upper surface is convex, and may also have other structures to adjust an angle of a beam spread in emitted light.

The encapsulation bodies 508 and 608 in FIGS. 10 and 11, respectively, may contain a wavelength conversion material such as a phosphor and/or a quantum dot. As the wavelength conversion material, various materials such as a phosphor and/or a quantum dot may be used.

As a phosphor, a phosphor represented by the following empirical formulae and colors may be used.

Oxide-based phosphor: Yellow and green Y₃Al₅O₁₂:Ce, Tb₃Al₅O₁₂:Ce, Lu₃Al₅O₁₂:Ce

Silicate-based phosphor: Yellow and green (Ba,Sr)₂SiO₄:Eu, Yellow and yellowish-orange (Ba,Sr)₃SiO₅:Ce

Nitride-based phosphor: Green β-SiAlON:Eu, Yellow La₃Si₆N₁₁:Ce, Yellowish-orange α-SiAION:Eu, Red CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y}, (0.5≦x≦3, 0<z<0.3, 0<y≦4) . . . Formula 1

In formula 1, Ln may be at least one element selected from a group consisting of group IIIa elements and rare-earth elements, and M may be at least one element selected from a group consisting of Ca, Ba, Sr and Mg.

Fluoride-based phosphor: KSF-based red K₂SiF₆:Mn₄⁺, K₂TiF₆:Mn₄⁺, NaYF₄:Mn₄⁺, NaGdF₄:Mn₄⁺

In addition, as a wavelength conversion material, a quantum dot (QD) may be used as a phosphor substitute or used by being mixed with a phosphor. The quantum dot may implement various colors according to a size thereof. In detail, when the quantum dot is used as a phosphor substitute, the quantum dot may be used as a red or green phosphor. In the case that the quantum dot is used, a narrow full width at half maximum, for example, about 35 mm, may be implemented.

Although the wavelength conversion material may be implemented in a manner in which it is contained in an encapsulation portion, the wavelength conversion material may also be previously formed in the form of a film to be used by being adhered to a surface of an optical structure such as a light emitting diode (LED) electronic component or a light guide plate. In this case, the wavelength conversion material may be easily applied to a required region in a uniform thickness structure.

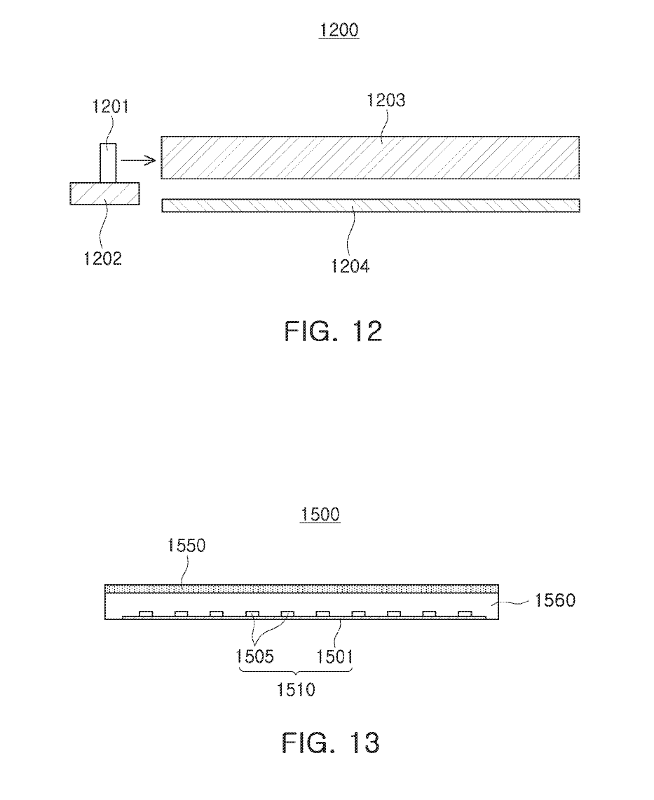

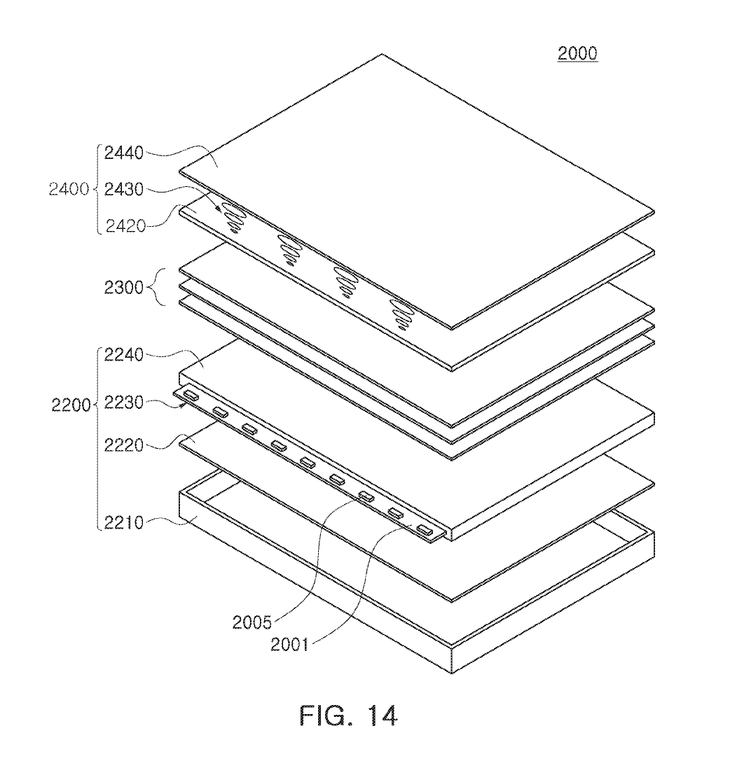

Such a wavelength conversion material may be used in various light source devices such as a backlight device, a display device, or a lighting device. FIGS. 12 and 13 are cross-sectional views of backlight devices according to various exemplary embodiments. FIG. 14 is an exploded perspective view of a display device according to an exemplary embodiment.

With reference to FIG. 12, a backlight device 1200 may include a light guide plate 1203, and a circuit board 1202 which is disposed on a side of the light guide plate 1203. A plurality of light sources 1201 may be mounted on the circuit board 1202. In the backlight device 1200, a reflective layer 1204 may be disposed below the light guide plate 1203.

The light source 1201 may emit light to a side of the light guide plate 1203 to be incident into the light guide plate 1203 and then be emitted upwardly of the light guide plate 1203. A backlight device according to this exemplary embodiment may be referred to as “an edge-type backlight device”. The light source 1201 may include the above-described semiconductor light emitting device or a semiconductor light emitting device package including the same, together with a wavelength conversion material. For example, the light source 1201 may be a semiconductor light emitting device package as described above (see, e.g., FIGS. 10 and 11).

With reference to FIG. 13, a backlight device 1500 may be a direct-type backlight device, and may include a wavelength converter 1550, a light source module 1510 arranged below the wavelength converter 1550, and a bottom case 1560 receiving the light source module 1510. In addition, the light source module 1510 may include a printed circuit board 1501, and a plurality of light sources 1505 mounted on an upper surface of the printed circuit board 1501. The light sources 1505 may be light sources such as the above-described semiconductor light emitting devices or semiconductor light emitting device packages including the same. In some exemplary embodiments, the wavelength conversion material may be omitted to the light sources.

The wavelength converter 1550 may be appropriately selected to emit white light according to a wavelength of light emitted from the light source 1505. The wavelength converter 1550 may be manufactured as a separate film to be used, and may also be provided as a form integrated with other optical elements such as a separate light diffusion plate. As such, in this exemplary embodiment, since the wavelength converter 1550 is disposed to be spaced apart from the light source 1505, deterioration in reliability of the wavelength converter 1550 due to heat discharged from the light source 1505 may be reduced.

FIG. 14 is a schematic exploded perspective view of a display device according to an exemplary embodiment.

With reference to FIG. 14, a display device 2000 may include a backlight device 2200, an optical sheet 2300, and an image display panel 2400 such as a liquid crystal panel.

The backlight device 2200 may include a bottom case 2210, a reflective plate 2220, and a light guide plate 2240, and a light source module 2230 provided on at least one side of the light guide plate 2240. The light source module 2230 may include a printed circuit board 2001 and a light source 2005. The light source 2005 may be a light source such as the above-described semiconductor light emitting devices or semiconductor light emitting device packages including the same. The light source 2005 employed in this exemplary embodiment may be a side view-type light emitting device mounted on a side thereof adjacent to a light emission surface. In addition, according to an exemplary embodiment, the backlight device 2200 may be substituted with one of the backlight devices 1200 and 1500 of FIGS. 12 and 13.

The optical sheet 2300 may be disposed between the light guide plate 2240 and the image display panel 2400, and may include several-types of sheets such as a diffusion sheet, a prism sheet, or a protective sheet.

The image display panel 2400 may display an image using light emitted through the optical sheet 2300. The image display panel 2400 may include an array substrate 2420, a liquid crystal layer 2430, and a color filter substrate 2440. The array substrate 2420 may include pixel electrodes disposed in a matrix form, thin film transistors applying an operating voltage to the pixel electrodes, and signal lines operating the thin film transistors. The color filter substrate 2440 may include a transparent substrate, a color filter, and a common electrode. The color filter may include filters through which light having a specific wavelength in white light emitted from the backlight device 2200 is selectively passed. The liquid crystal layer 2430 may be re-arranged by an electrical field formed between the pixel electrodes and the common electrode to control light transmittance. Light of which transmittance is adjusted may pass through the color filter of the color filter substrate 2440 to display an image. The image display panel 2400 may further include a driving circuit unit processing an image signal, and the like.

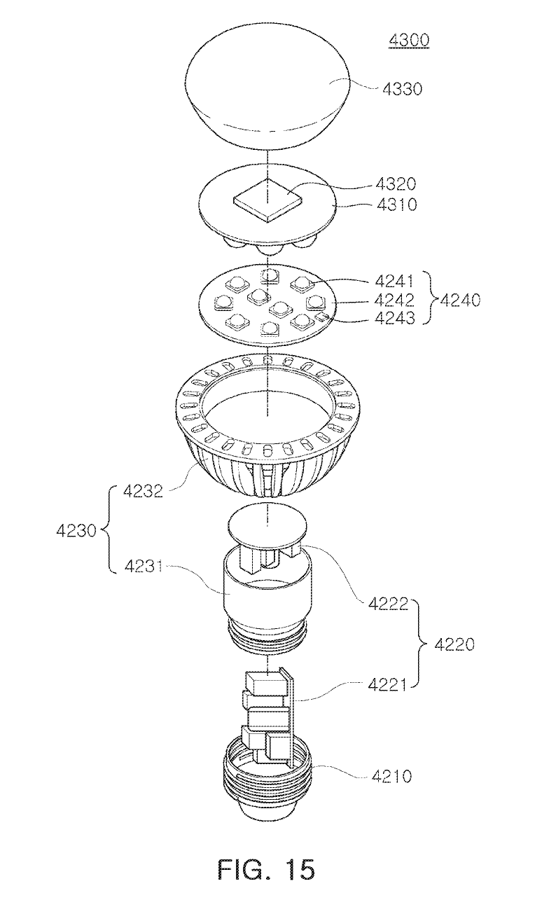

FIG. 15 is an exploded perspective view of an LED lamp employing a semiconductor light emitting device according to an exemplary embodiment therein.

With reference to FIG. 15, a lighting device 4300 may include a socket 4210, a power supply 4220, a heat sink 4230, and a light source module 4240. According to some exemplary embodiments, the light source module 4240 may include a light emitting device array, and the power supply 4220 may include a light emitting device driving portion.

The socket 4210 may be configured to be substituted with an existing lighting device. Power supplied to the lighting device 4200 may be applied through the socket 4210 thereto. As illustrated in FIG. 15, the power supply 4220 may include a first power supply portion 4221 and a second power supply portion 4222 that are separated from or coupled to each other. The heat sink 4230 may include an internal radiation portion 4231 and an external radiation portion 4232. The internal radiation portion 4231 may be directly connected to the light source module 4240 and/or the power supply 4220, by which heat may be transferred to the external radiation portion 4232.

The light source module 4240 may receive power from the power supply 4220 to emit light to an optical module 4330. The light source module 4240 may include light sources 4241, a circuit board 4242, and a controller 4243, and the controller 4243 may store driving information of the light sources 4241 therein. The light source may be a light source according to the above-described semiconductor light emitting devices or a semiconductor light emitting device packages including the same.

A reflective plate 4310 may be provided above the light source module 4240. The reflective plate 4310 may allow for uniform spreading of light from a light source sideways and backwards so as to reduce a glare effect. A communications module 4320 may be mounted on an upper portion of the reflective plate 4310, and home-network communications may be implemented through the communications module 4320. For example, the communications module 4320 may be a wireless communications module using ZigBee, Wi-Fi, or Li-Fi, and may control illumination of a lighting device installed indoors or outdoors, such as switching on/off of a lighting device, adjustment of brightness, or the like, through a smartphone or a wireless controller. In addition, electronic products in the home or outdoors, or in automobile systems, such as TV sets, refrigerators, air conditioners, door locks, automobiles, or the like, may be controlled using a Li-Fi communications module that uses a visible light wavelength of a lighting device installed indoors or outdoors. The reflective plate 4310 and the communications module 4320 may be covered by a cover 4330.

As set forth above, according to exemplary embodiments, a second finger electrode may be disposed in a trench in which a first finger electrode is located, thereby preventing light loss due to a second finger electrode to exhibit improved light output.

While exemplary embodiments have been shown and described above, it will be apparent to those skilled in the art that modifications and variations could be made without departing from the scope of the present disclosure as defined by the appended claims.

1. A semiconductor light emitting device comprising:
a semiconductor stack including a first conductivity-type semiconductor layer, a second conductivity-type semiconductor layer, an active layer between the first and second conductivity-type semiconductor layers, and a trench penetrating through the second conductivity-type semiconductor layer and the active layer to expose a portion of the first conductivity-type semiconductor layer;
a first insulating layer disposed on an inner sidewall of the trench;
a current spreading layer disposed on the second conductivity-type semiconductor layer;
a first finger electrode disposed on the portion of the first conductivity-type semiconductor layer;
a second insulating layer disposed on the exposed portion of the first conductivity-type semiconductor layer to cover the first finger electrode; and
a second finger electrode disposed in the trench and connected to the current spreading layer.

2. The semiconductor light emitting device of claim 1, wherein the second finger electrode is disposed on the second insulating layer to overlap the first finger electrode.

3. The semiconductor light emitting device of claim 2, wherein the second finger electrode has a width greater than a width of the first finger electrode.

4. The semiconductor light emitting device of claim 2, wherein the current spreading layer extends into the trench along an upper surface of the first insulating layer.

5. The semiconductor light emitting device of claim 4, wherein a region in which the second finger electrode and the current spreading layer are connected to each other is located in the trench.

6. The semiconductor light emitting device of claim 1, wherein the second finger electrode is disposed on the second insulating layer and has an extension portion extending in a width direction to connect to a portion of the current spreading layer disposed outside of the trench.

7. The semiconductor light emitting device of claim 6, wherein the extension portion extending in the width direction is provided as a plurality of extension portions, and the plurality of extension portions are arranged along a length direction of the second finger electrode and spaced apart from each other.

8. The semiconductor light emitting device of claim 1, wherein the current spreading layer extends into the trench along an upper surface of the first insulating layer, and the second finger electrode is disposed on a portion of the current spreading layer located in the trench.

9. The semiconductor light emitting device of claim 8, wherein the second finger electrode comprises two branched electrodes respectively disposed on portions of the current spreading layer that are adjacent to the first finger electrode.

10. The semiconductor light emitting device of claim 9, wherein a portion of the second finger electrode is located on a portion of the current spreading layer disposed on an upper surface of the second conductivity-type semiconductor layer.

11. The semiconductor light emitting device of claim 1, wherein the first insulating layer extends to a portion of an upper surface of the second conductivity-type semiconductor layer being adjacent to the trench.

12. The semiconductor light emitting device of claim 1, wherein the current spreading layer comprises a transparent electrode layer.

13. The semiconductor light emitting device of claim 12, wherein the current spreading layer comprises at least one of indium tin oxide (ITO), zinc-doped indium tin oxide (ZITO), zinc indium oxide (ZIO), gallium indium oxide (GI), zinc tin oxide (ZTO), fluorine-doped tin oxide (FTO), aluminum-doped zinc oxide (AZO), gallium-doped zinc oxide (GZO), In₄Sn₃O₁₂, and Zn₍₁₋ₓ₎MgO (zinc magnesium oxide, 0≦x≦1).

14. The semiconductor light emitting device of claim 1, further comprising a first electrode pad connected to the first finger electrode and a second electrode pad connected to the second finger electrode.

15. The semiconductor light emitting device of claim 1, wherein a portion of the second finger electrode is disposed on the second conductivity-type semiconductor layer,
the semiconductor light emitting device further comprising a current blocking layer disposed between a portion of the second finger electrode and the second conductivity-type semiconductor layer.

16. A semiconductor light emitting device comprising:
a semiconductor stack including a first conductivity-type semiconductor layer, a second conductivity-type semiconductor layer, an active layer between the first and second conductivity-type semiconductor layers, and a trench penetrating through the second conductivity-type semiconductor layer and the active layer to expose a portion of the first conductivity-type semiconductor layer;
a first insulating layer disposed on an inner sidewall of the trench;
a current spreading layer disposed on the second conductivity-type semiconductor layer and extending along an upper surface of the first insulating layer;
a first finger electrode disposed on the exposed portion of the first conductivity-type semiconductor layer;
a second insulating layer disposed in the trench to cover a portion of the current spreading layer together with the first finger electrode; and
a second finger electrode disposed on the second insulating layer and connected to the current spreading layer.

17. The semiconductor light emitting device of claim 16, wherein the second finger electrode has a width greater than a width of the first finger electrode, and the second finger electrode has a region overlapping the first finger electrode in a length direction.

18. The semiconductor light emitting device of claim 16, wherein the second finger electrode is disposed on a portion of the current spreading layer located in the trench.

19. The semiconductor light emitting device of claim 16, wherein the first insulating layer comprises an extension portion extending toward a portion of an upper surface of the second conductivity-type semiconductor layer that is adjacent to the trench.

20. A semiconductor light emitting device comprising:
a semiconductor stack including a first conductivity-type semiconductor layer, a second conductivity-type semiconductor layer, an active layer between the first and second conductivity-type semiconductor layers, and a trench penetrating through the second conductivity-type semiconductor layer and the active layer to expose a portion of the first conductivity-type semiconductor layer;
a current spreading layer disposed on an upper surface of the second conductivity-type semiconductor layer;
a first finger electrode disposed on the exposed portion of the first conductivity-type semiconductor layer in the trench;
an insulating layer disposed in the trench to cover the first finger electrode; and
a second finger electrode disposed on an upper surface of the insulating layer and connected to a portion of the current spreading layer being adjacent to the trench.

21-32. (canceled)
